(19) United States
(12) Patent Application Publication
(10) Pub. No.: US 2006/0261373 A1
(43) Pub. Date: Nov. 23, 2006

(54) Transistor structure and electronics device

(75) Inventor: Toru Takahashi, Katsuragi-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/434,269

(22) Filed: May 16, 2006

(30) Foreign Application Priority Data
May 23, 2005 (JP) P2005-149683

(51) Int. Cl. H01L 31/00

(52) U.S. Cl. 257/197

(57) ABSTRACT

Provided is a transistor structure which is capable of avoiding electric field concentration without increase in cell size and of enlarging its safe operating area and in addition, of decreasing the saturation voltage across a collector and a emitter more than in the case of a conventional ballast resistor layout method. A first base wiring and a second base wiring are connected to each other, not by a conductive material, but by only a base layer, and the base layer through which the first base wiring and the second base wiring are connected, functions as a ballast resistor. This makes it possible to avoid the electric field concentration without increase in cell size and to enlarge its safe operating area and in addition, to decrease the saturation voltage across the collector and the emitter more than in a case of the conventional ballast resistor layout method.

### BACKGROUND OF THE INVENTION

1. Field of the Invention

The present invention relates to a transistor structure and an electronics device. More particularly, the invention relates to a technique which is effectively applied to high-current and medium-current transistors and employed in electronics devices including, for instance, semiconductor devices such as a regulator, an inverter, a motor drive, a lamp drive, and a DC-DC converter.

2. Description of the Related Art

FIG. 12A is a plan view showing a relevant part of a mesh-emitter PNP transistor of conventional design, and FIG. 12B is a sectional view taken on line K-K of FIG. 12A. A P-type epitaxial layer 2 is formed on a surface of a P-type semiconductor substrate 1 to be a collector layer. On a surface of the P-type epitaxial layer 2 is formed an N-type base layer 3, and on a surface of the N-type base layer is formed a P-type mesh-emitter layer 4 which is an emitter layer formed in a mesh shape.

A chip surface is covered with an insulating layer 5 such as a silicon dioxide film. The insulating layer 5 of the chip surface is provided with a first base wiring 6 and a base electrode which are formed of a conductive material. Island-shaped base layers 3a are formed in the mesh-emitter layer 4. A base contact opening 7 is provided in the insulating layer 5 on this island-shaped base layer 3a and on a base layer 3b around a periphery of the mesh-emitter layer 4 which base layer 3b is partially surrounded by the mesh-emitter layer 4. The base layers 3a and 3b are electrically connected to a second base wiring 8 through a filling portion 8a of a conductive material which fills the base contact opening 7. The first base wiring 6 and the second base wiring 8 are electrically connected through the conductive material.

In the insulating layer 5 on the mesh-emitter layer 4, an emitter-contact opening 9 is provided. The mesh-emitter layer 4 is electrically connected to an emitter wiring (not shown) and an emitter electrode (not shown) through a filling portion of a conductive material which fills the emitter-contact opening 9. Furthermore, on a reverse of a P-type semiconductor substrate 1 to be a collector layer, is provided a collector electrode 10, and a PNP transistor is thus configured.

FIG. 13A is a plan view showing a relevant part of a mesh-emitter PNP transistor of conventional design, which is provided with a ballast resistor, and FIG. 13B is a sectional view taken on line M-M of FIG. 13A. Such a transistor structure is disclosed in Japanese Unexamined Patent Publication JP-A 64-59857(1989), for instance. Island-shaped base layer 3a is formed in the mesh-emitter layer 4. In the island base layer 3a and in the base layer 3b around the periphery of the emitter layer 4 which base layer 3b is partially surrounded by the emitter layer, is formed a diffusion layer 11 having the same polarity, that is of the same conductivity type, as the emitter diffusion layer which constitutes the emitter layer 4. This makes a current pathway from a base electrode to the emitter diffusion layer narrower, thereby increasing a base-emitter resistance. The resistor as described above is generally referred to as a ballast resistor 12. By means of this ballast resistor 12, a base current can be restricted so that a safe operating area can be enlarged.

In recent years, miniaturization of chip area in an semiconductor element has been developing in order to reduce prices thereof. However, the miniaturization of chip area gives rise to a problem of increase in a saturation voltage across a collector and an emitter of a transistor.

FIG. 14 is a plan view schematically showing a cell of a transistor having a mesh-emitter structure. The above mentioned “cell” is, in a case of a transistor of conventional design having the mesh-emitter structure, a single transistor which is composed of one island-shaped base region formed in the mesh-emitter, and an emitter region surrounding the island-shaped base region. In order to avoid the above problem, a simple technique is available that a cell size is reduced while an emitter boundary length is secured so that the saturation voltage across the collector and the emitter is decreased. However, in this case, operation of the transistor with the voltage in a high range across the collector and the emitter gives rise to an electric field concentration on a local area of the transistor, with the result that the safe operating area becomes narrower.

Since a ballast resistor is disposed in a technique described in the JP-A 64-59857(1989), it is an advantage that the safe operating area is enlarged. However, the technique has the following problems. (1) The saturation voltage across the collector and the emitter is increased. (2) It becomes difficult to reduce the cell size and the chip price.

### SUMMARY OF THE INVENTION

An object of the invention is to provide a transistor structure and an electronics device which can avoid electric field concentration without increase in cell size and enlarge its safe operating area and furthermore, makes it possible to decrease the saturation voltage across a collector and an emitter more than a conventional ballast resistor layout method.

The invention provides a transistor structure having a base layer formed in a collector layer on a chip surface of a planar semiconductor, the transistor structure comprising:

an emitter layer formed in a base layer; and

an insulating layer formed on the base layer,

wherein a first base contact opening is formed in the insulating layer;

the first base contact opening is filled with a conductive material;

a first base wiring and a base electrode are formed on the insulating layer;

a second base contact opening is formed in the insulating layer on the base layer between the first base contact opening and the emitter layer which base layer is formed in the emitter layer or between the emitter layers;

the second base contact opening is filled with a conductive material;

a second base wiring is formed on the insulating layer; and

the first base wiring and the second base wiring are connected to each other by the base layer.

According to the invention, the first wiring and the second wiring are connected to each other, not by the conductive material, but by the base layer so that the following effects can be obtained. It is possible to avoid electric field concentration without increase in cell size and enlarge its safe operating area.

Furthermore, the saturation voltage across a collector and an emitter can be decreased so as to be lower than in the case of a conventional ballast resistor layout method.

Further, in the invention, it is preferable that a diffusion layer of the same conductivity type as the emitter layer is formed in the base layer through which the first base wiring and the second base wiring are connected to each other.

Further, according to the invention, the diffusion layer of the same conductivity type as the emitter layer is formed in the base layer through which the first base wiring and the second base wiring are connected to each other, with the result that a current pathway from the base electrode to the diffusion layer becomes narrower, thereby increasing a base-emitter resistance.

Consequently, it is possible to enlarge the safe operating area.

Further, in the invention, it is preferable that a plurality of island-shaped diffusion layer of the same conductivity type as the emitter layer are formed in the base layer through which the first base wiring and the second base wiring are connected to each other.

Further, according to the invention, a plurality of island-shaped diffusion layer of the same conductivity type as the emitter layer are formed in the base layer so that a ballast resistance can be realized by these island-shaped diffusion layers. This makes it possible to achieve more reduction in cell size, compared to the conventional structure in which the emitter layer and the diffusion layer are applied in series with each other.

Further, in the invention, it is preferable that the base layer through which the first base wiring and the second base wiring are connected to each other, is formed into a mesh shape.

Further, according to the invention, the base layer formed in a mesh shape makes it possible to avoid electric field concentration without increase in cell size and enlarge its safe operating area and in addition, to decrease the saturation voltage across a collector and an emitter more than a conventional ballast resistor layout method.

Further, in the invention, it is preferable that the first base contact opening is formed in a mesh shape.

Further, according to the invention, the first base contact opening is formed, with the result that a current pathway of the first base contact which is a filling portion of a conductive material which fills the first base contact opening, becomes narrower, thereby increasing a base-emitter resistance. Consequently, it is possible to enlarge the safe operating area.

Further, in the invention, it is preferable that an end portion of a filling portion of the conductive material portion which fills the continuous first base contact opening has a half length of cell distance in a direction parallel to an extending direction of the first base contact opening between the second base contact openings.

Further, according to the invention, the end portion of the filling portion of the conductive material which fills the first base contact opening has a half length of cell distance in a direction parallel to an extending direction of the first base contact opening between the second base contact openings, so that it is made possible to equalize base currents flowing from the second base wirings.

Further, in the invention, it is preferable that the first base contact opening is disposed so that an extending direction thereof cuts across the second base wiring.

Further, according to the invention, the first base contact opening is disposed so that an extending direction thereof cuts across the second base wiring. Such constitution and disposition of the first base contact enable to equalize base currents flowing from a plurality of the second base wirings.

Further, in the invention, it is preferable that the transistor is a mesh-emitter transistor of which emitter layer is formed in a mesh shape to be a mesh-emitter layer.

Further, in the invention, it is preferable that the transistor is a multi-emitter transistor having an emitter layer composed of a plurality of island-shaped emitter layers.

Further, according to the invention, the mesh-emitter transistor or the multi-emitter transistor can be realized which makes it possible to avoid electric field concentration without increase in cell size and enlarge its safe operating area, and in addition, to decrease the saturation voltage across a collector and an emitter.

Further, the invention provides an electronics device comprising the transistor structure mentioned above.

According to the invention, it is possible to realize the electronics device including such a transistor structure.

### BRIEF DESCRIPTION OF THE DRAWINGS

Other and further objects, features, and advantages of the invention will be more explicit from the following detailed description taken with reference to the drawings wherein:

FIG. 1A is a plan view showing a relevant part of a mesh-emitter PNP transistor according to a first embodiment of the invention, and FIG. 1B is a sectional view taken on line A-A of FIG. 1A;

FIG. 2A is a plan view showing a relevant part of a multi-emitter PNP transistor according to a second embodiment of the invention, and FIG. 2B is a sectional view taken on line B-B of FIG. 2A;

FIG. 3A is plan view showing a relevant part of a mesh-emitter PNP transistor according to a third embodiment of the invention, and FIG. 3B is a sectional view taken on line C-C of FIG. 3A;

FIG. 4A is a plan view showing a relevant part of a multi-emitter PNP transistor according to a modified example of the third embodiment, and FIG. 4B is a sectional view taken on line D-D of FIG. 4A;

FIG. 5A is a plan view showing a relevant part of a mesh-emitter PNP transistor according to a fourth embodiment of the invention, and FIG. 5B is a sectional view taken on line E-E of FIG. 5A;

FIG. 6A is a plan view showing a relevant part of a multi-emitter PNP transistor according to a modified example of the fourth embodiment, and FIG. 6B is a sectional view taken on line F-F of FIG. 6A;

FIG. 7A is a plan view of a relevant part of a mesh-emitter PNP transistor according to a fifth embodiment of the invention, and FIG. 7B is a sectional view taken on line G-G of FIG. 7A;

FIG. 8A is a plan view of a relevant part of a multi-emitter PNP transistor according to a modified example of the fifth embodiment, and FIG. 8B is a sectional view taken on line H-H of FIG. 8A;

FIG. 9A is a plan view showing a relevant part of a mesh-emitter PNP transistor according to a sixth embodiment of the invention, and FIG. 9B is a sectional view taken on line I-I of FIG. 9A;

FIG. 10A is a plan view showing a relevant part of a multi-emitter PNP transistor according to a modified example of the sixth embodiment, and FIG. 10B is a sectional view taken on line J-J of FIG. 10A;

FIG. 11 is a plan view schematically showing a mesh-emitter PNP transistor according to a seventh embodiment of the invention;

FIG. 12A is a plan view showing a relevant part of a related art mesh-emitter PNP transistor, and FIG. 12B is a section view taken on line K-K of FIG. 12A;

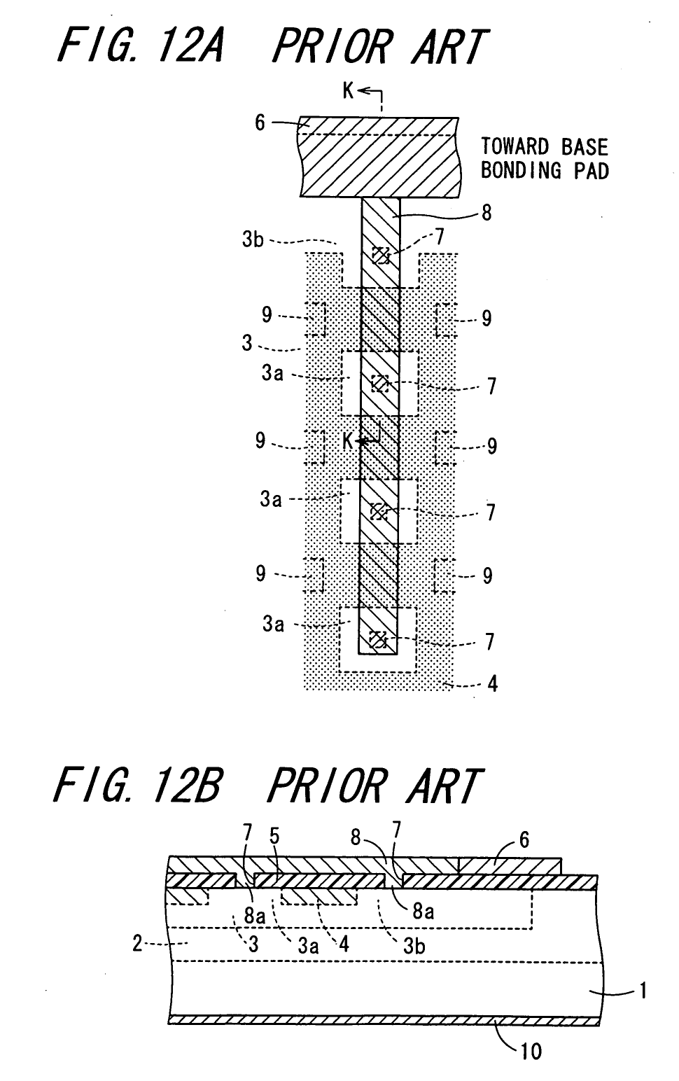

FIG. 13A is a plan view showing a relevant part of a related art mesh-emitter PNP transistor having a ballast resistance, and FIG. 13B is a section view taken on line M-M of FIG. 13A; and

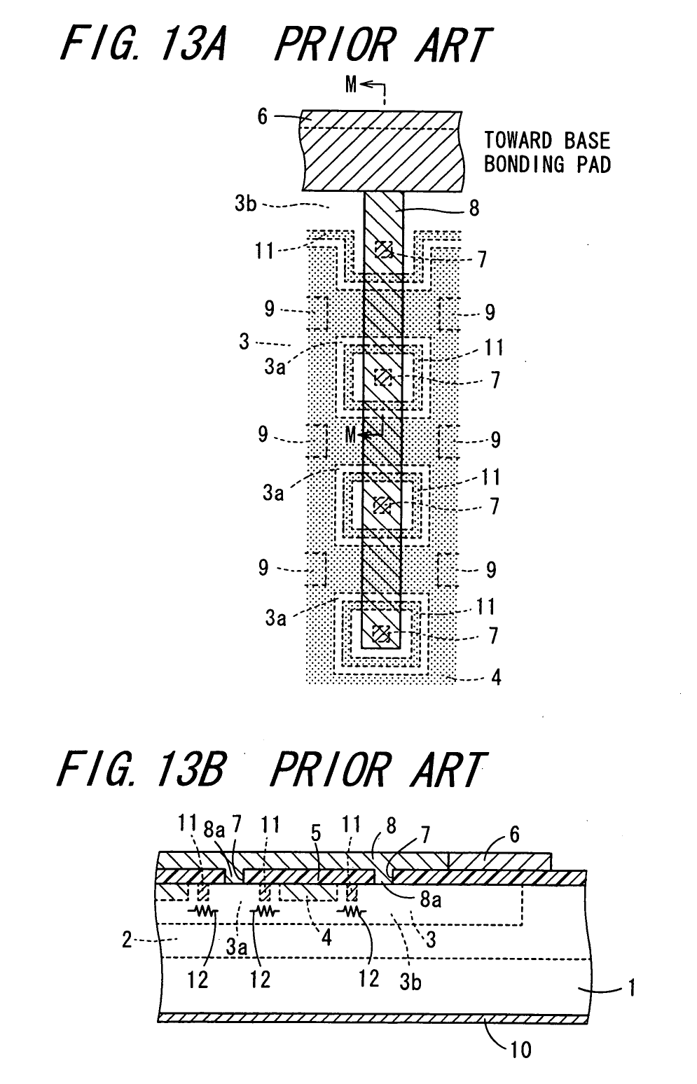

FIG. 14 is a plan view schematically showing a cell of a transistor having a mesh-emitter structure.

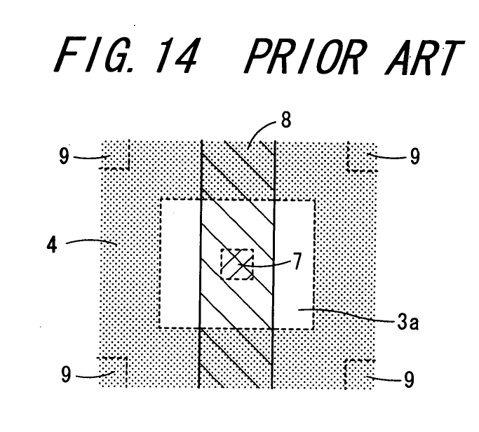

### DETAILED DESCRIPTION OF THE PREFERED EMBODIMENTS

Hereinafter, with reference to the drawings, a plurality of embodiments for practice of the invention will be described. In each of the embodiments, components corresponding to items described in a precedent embodiment will be denoted by the same reference numeral, and overlapping description may be omitted. In a case where only a part of constitution is described, the other parts thereof should be construed as the same as those in a previously described embodiment. Not only a combination of the parts which are specifically described in each of the embodiments, but also a partial combination of the embodiments is achievable unless troubles are caused in the combination.

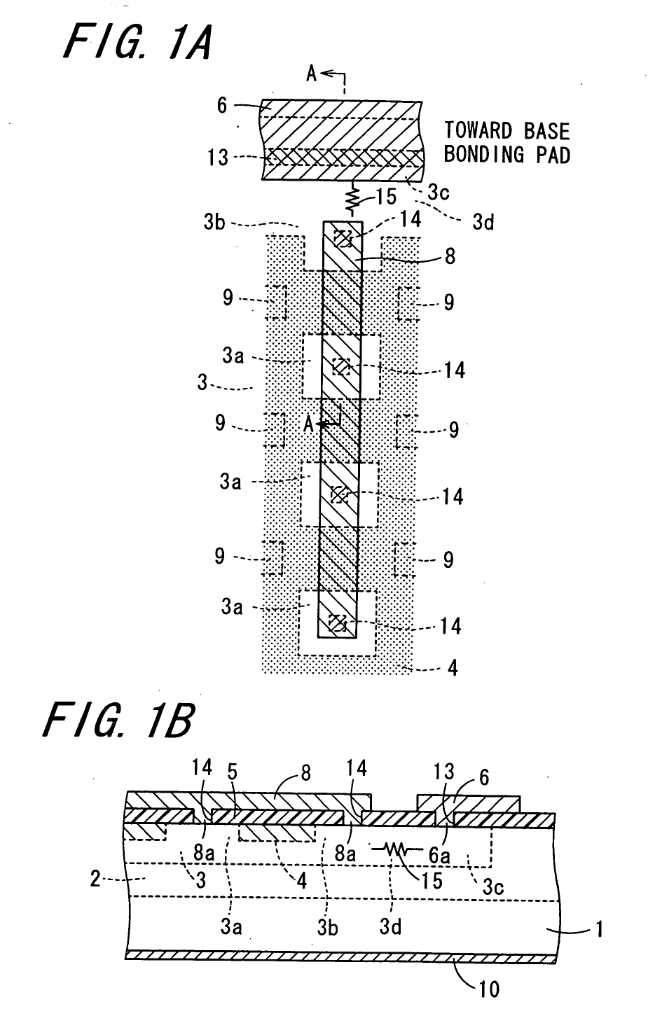

FIG. 1A is a plan view showing a relevant part of a mesh-emitter PNP transistor according to a first embodiment of the invention, and FIG. 1B is a sectional view taken on line A-A of FIG. 1A. A transistor structure according to the embodiment is employed in electronics devices including, for instance, semiconductor devices such as a regulator, an inverter, a motor drive, a lamp drive, and a DC-DC converter. However, application of the transistor structure is not limited to these electronics devices. In the mesh-emitter PNP transistor (referred to as a first transistor) according to the first embodiment, a P-type epitaxial layer 2 is formed on a surface of a P-type semiconductor substrate 1 to be a collector layer. On a surface of the P-type epitaxial layer 2 is formed an N-type base layer 3. On a surface of the N-type base layer 3 is formed a P-type mesh-emitter layer 4 which is an emitter layer formed in a mesh shape.

On the base layer 3 provided with a mesh-emitter layer 4 is formed an insulating layer 5 such as a silicon dioxide film. The insulting layer 5 on a base layer 3c situated in a laterally outward direction from the mesh-emitter 4 is provided with a first base contact opening 13. This first base contact opening 13 is filled with a conductive material. On the insulating layer 5 are formed a first base wiring 6 and a base electrode which are electrically connected to the base layer 3c through the conductive material. In other words, the base layer 3c is electrically connected to the first base wiring 6 and the base electrode via a filling portion 6a of the conductive material which fills the first base contact opening 13. A second base contact opening 14 is provided in the insulating layer 5 on an island-shaped base layer 3 which indicates a base layer 3a surrounded by the mesh-emitter layer 4, and on a base layer 3b around a periphery of the mesh-emitter layer 4 which base layer 3b is partially surrounded by the mesh-emitter layer 4. The second base contact opening 14 is filled with a conductive material. On the insulating layer 5 is formed a second base wiring 8 which is electrically connected to the island-shaped base layer 3a and the base layer 3b around the periphery of the mesh-emitter layer through the conductive material. In other words, the island-shaped base layer 3a and the base layer 3b around the periphery of the mesh-emitter layer 4 are electrically connected to the second base wiring 8 via a filling portion 8a of the conductive material which fills the second base contact opening 14. The insulating layer 5 on the mesh-emitter layer 4 is provided with an emitter contact opening 9. The mesh-emitter layer 4 is electrically connected to an emitter wiring (not shown) and an emitter electrode (not shown) via a filling portion of a conductive material which fills the emitter contact opening 9. Furthermore, on a reverse of a P-type semiconductor substrate 1 to be a collector layer, is provided a collector electrode 10, and a PNP transistor is thus configured. The first base wiring 6 and the second base wiring 8 are connected to each other, not by the conductive material, but by only a base layer 3d between the filling portions 6a and 8a. The base layer 3d through which the first base wiring 6 and the second base wiring 8 are connected to each other, functions as a ballast resistor 15.

According to the first transistor as described above, the first base wiring 6 and the second base wiring 8 are connected to each other, not by the conductive material, but by only the base layer 3d so that the following effects can be obtained. It is possible to avoid electric field concentration without increase in cell size (for instance, a size of cell having a rectangular shape with 85 μm on one side, 60 μm on the other side). In addition, it is also possible to enlarge its safe operating area. Furthermore, the saturation voltage across the collector and the emitter can be decreased so as to be lower than in the case of a conventional ballast resistor layout method. A table 1 specifically shows levels of items such as the safe operating areas under the collector-emitter voltage of 20V and the collector-emitter saturation voltages, respectively regarding the transistor of the invention (the invention structure) and the transistor of the conventional design (the conventional structure).

TABLE 1

| | | Conventional structure | |
|---|---|---|---|
| | | Ballast | Ballast |
| | Invention | resistor: | resistor: |
| | Structure | absent | present |
| Chip size | 1.43 × 1.07 | 1.43 × 1.07 mm | 1.43 × 1.07 mm |
| | mm | | |
| Cell size | 85 × 60 μm | 85 × 60 μm | 110 × 85 μm |
| Safe operating area | Endured to | Endured to | Endured to |
| VCE = 22.5 V | collector | collector | collector |
| | current of | current of | current of |
| | 1.2 A | 0.56 V | 1.2 A |
| Collector-emitter | 0.47 V | 0.3 V | 0.62 V |
| saturation voltage | | | |

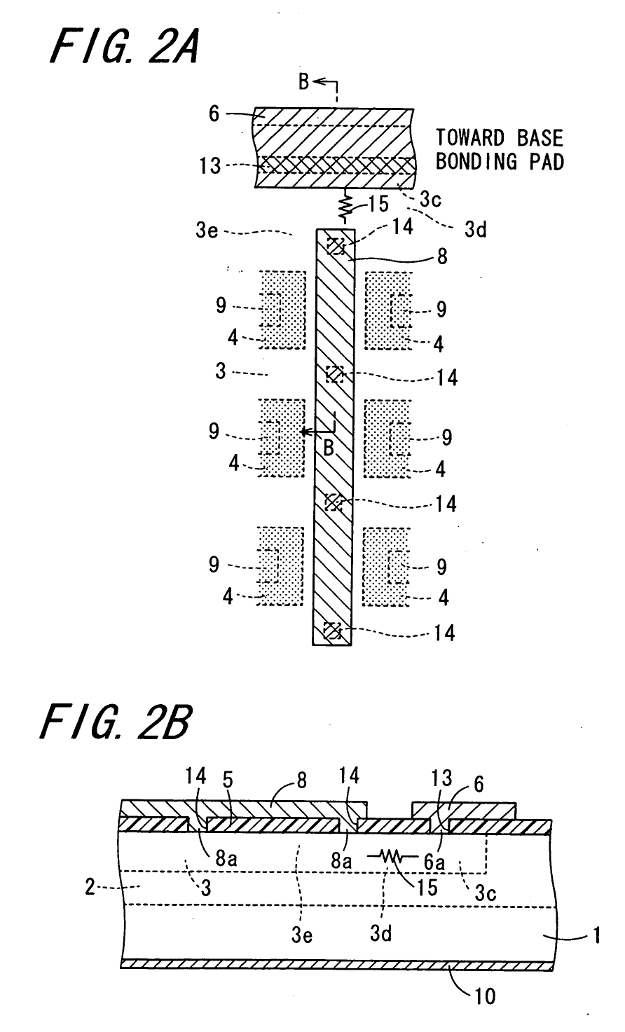

FIG. 2A is a plan view showing a relevant part of a multi-emitter PNP transistor according to a second embodiment of the invention, and FIG. 2B is a sectional view taken on line B-B of FIG. 2A. In the multi-emitter PNP transistor (referred to as a second transistor) according to the second embodiment, a P-type epitaxial layer 2 is formed on a surface of a P-type semiconductor substrate 1 to be a collector layer. On a surface of the P-type epitaxial layer 2 is formed an N-type base layer 3. On a surface of the base layer 3 is formed a P-type emitter layer 4. This emitter layer 4 is formed on the base layer 3 as a plurality of island-shaped emitter layers.

On the base layer 3 provided with the emitter layer 4 is formed an insulating layer 5 such as a silicon dioxide film. The insulting layer 5 on a base layer 3c situated in a laterally outward direction from the mesh-emitter 4 is provided with a first base contact opening 13. This first base contact opening 13 is filled with a conductive material. On the insulating layer 5 are formed a first base wiring 6 and a base electrode which are electrically connected to the base layer 3c through the conductive material. In other words, the base layer 3c is electrically connected to the first base wiring 6 and the base electrode via a filling portion 6a of the conductive material which fills the first base contact opening 13. A second base contact opening 14 is provided in the insulating layer 5 on a base layer 3e formed between a plurality of the island-shaped emitter layers 4. The second base contact opening 14 is filled with a conductive material. On the insulating layer 5 is formed a second base wiring 8 which is connected to the base layer 3e formed between the island-shaped emitter layers 4 through the conductive material. In other words, the base layer 3e formed between the island-shaped emitter layers 4 is electrically connected to the second base wiring 8 via a filling portion 8a of the conductive material which fills the second base contact opening 14. The insulating layer 5 on the island-shaped emitter layer 4 is provided with an emitter contact opening 9. The island-shaped emitter layer 4 is electrically connected to an emitter wiring (not shown) and an emitter electrode (not shown) via a filling portion of a conductive material in the emitter contact opening 9. Furthermore, on a reverse of a P-type semiconductor substrate 1 to be a collector layer, is provided a collector electrode 10, and a PNP transistor is thus configured. The first base wiring 6 and the second base wiring 8 are connected to each other, not by the conductive material, but by only the base layer 3d between the filling portions 6a and 8a. The base layer 3d through which the first base wiring 6 and the second base wiring 8 are connected to each other, functions as a ballast resistor 15.

According to the second transistor as described above, the first base wiring 6 and the second base wiring 8 are connected to each other, not by the conductive material, but by only the base layer 3d so that the same effects as those achieved in the first transistor can be obtained. Briefly, also in the multi-emitter PNP transistor, it is possible to avoid electric field concentration without increase in cell size and to enlarge its safe operating area. Furthermore, the saturation voltage across the collector and the emitter can be decreased so as to be lower than in the case of a conventional ballast resistor layout method.

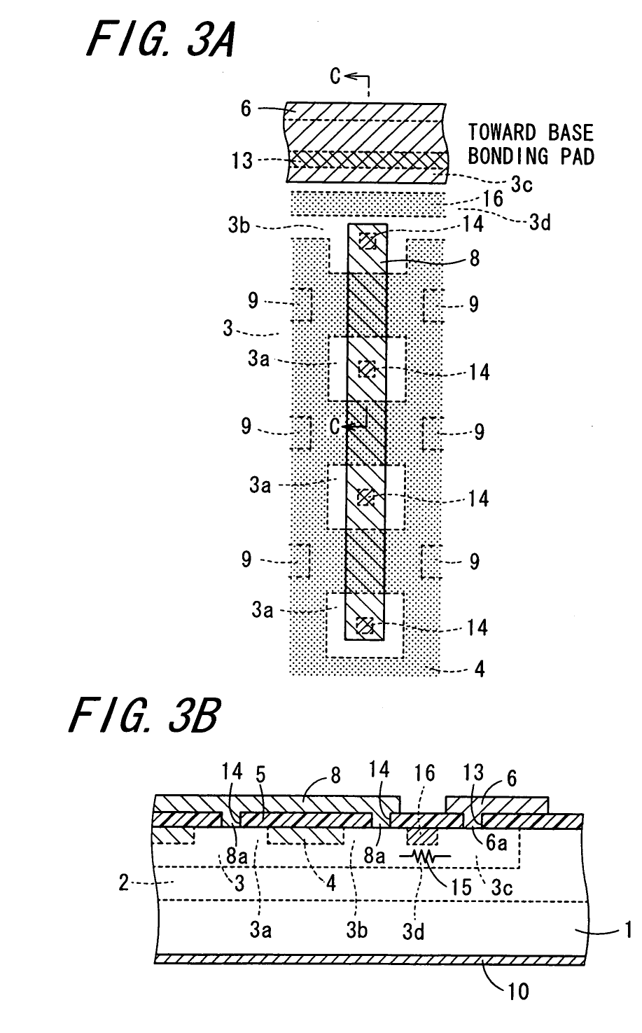

FIG. 3A is a plan view showing a relevant part of a mesh-emitter PNP transistor according to a third embodiment of the invention, and FIG. 3B is a sectional view taken on line C-C of FIG. 3A. In the mesh-emitter PNP transistor (referred to as a third transistor) according to the third embodiment, a diffusion layer 16 of the same conductivity type as a P-type emitter diffusion layer 4, is formed on the base layer 3d through which the first base wiring 6 and the second base wiring 8 are connected to each other. The base layer 3d through which the first base wiring 6 and the second base wiring 8 are connected to each other, functions as a ballast resistor 15. The third transistor has the same constitution regarding the other parts thereof as those of the first transistor.

According to the third transistor as described above, the diffusion layer 16 of the same conductivity type as the emitter layer 4, is formed on the base layer 3d through which the first base wiring 6 and the second base wiring 8 are connected to each other, with the result that a current pathway from the base electrode to the diffusion layer 16 becomes narrower, thereby increasing a base-emitter resistance. Consequently, it is possible to enlarge the safe operating area. The third transistor exerts more effects which are the same as those achieved by the first transistor.

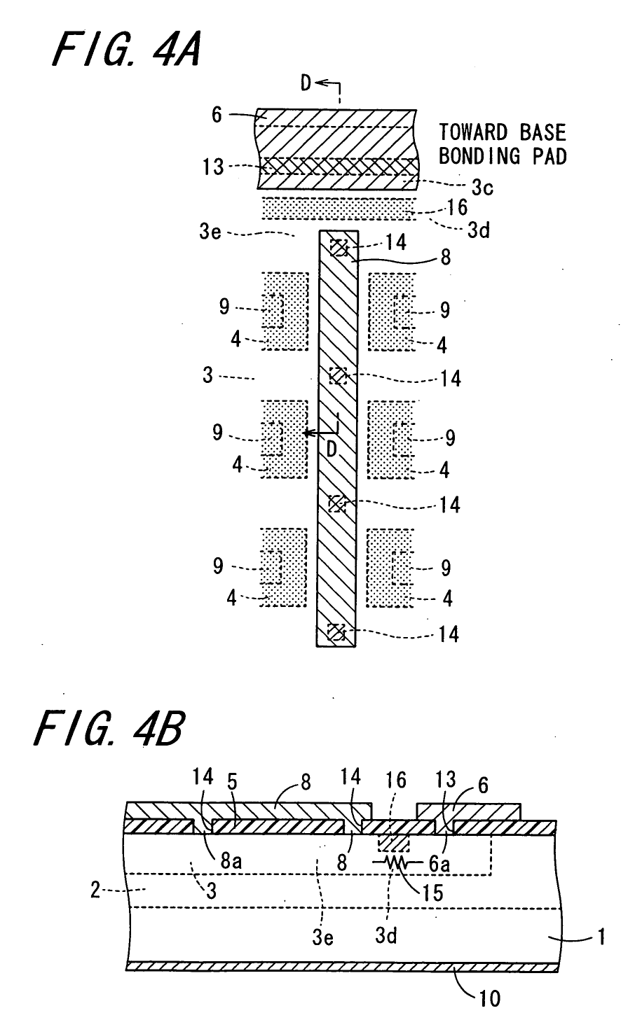

FIG. 4A is a plan view showing a relevant part of a multi-emitter PNP transistor according to a modified example of the third embodiment, and FIG. 4B is a sectional view taken on line D-D of FIG. 4A. In the multi-emitter PNP transistor according to the modified example, a diffusion layer 16 of the same conductivity type as the P-type emitter layer 4, is formed on the base layer 3d through which the first base wiring 6 and second base wiring 8 of the multi-emitter PNP transistor are connected to each other. The base layer 3d through which the first base wiring 6 and the second base wiring 8 are connected to each other, functions as a ballast resistor 15. The multi-emitter PNP transistor according to the modified example has the same constitution regarding the other parts thereof as those of the multi-emitter PNP transistor according to the second embodiment.

According to the multi-emitter PNP transistor according to the modified example as described above, the diffusion layer 16 of the same conductivity type as the P-type emitter layer, is formed on the base layer 3d through which the first base wiring 6 and the second base wiring 8 are connected to each other, with the result that a current pathway from the base electrode to the diffusion layer 16 becomes narrower, thereby increasing a base-emitter resistance. Consequently, it is possible to enlarge the safe operating area. The multi-emitter PNP transistor according to the modified example exerts more effects which are the same as those achieved by the second transistor.

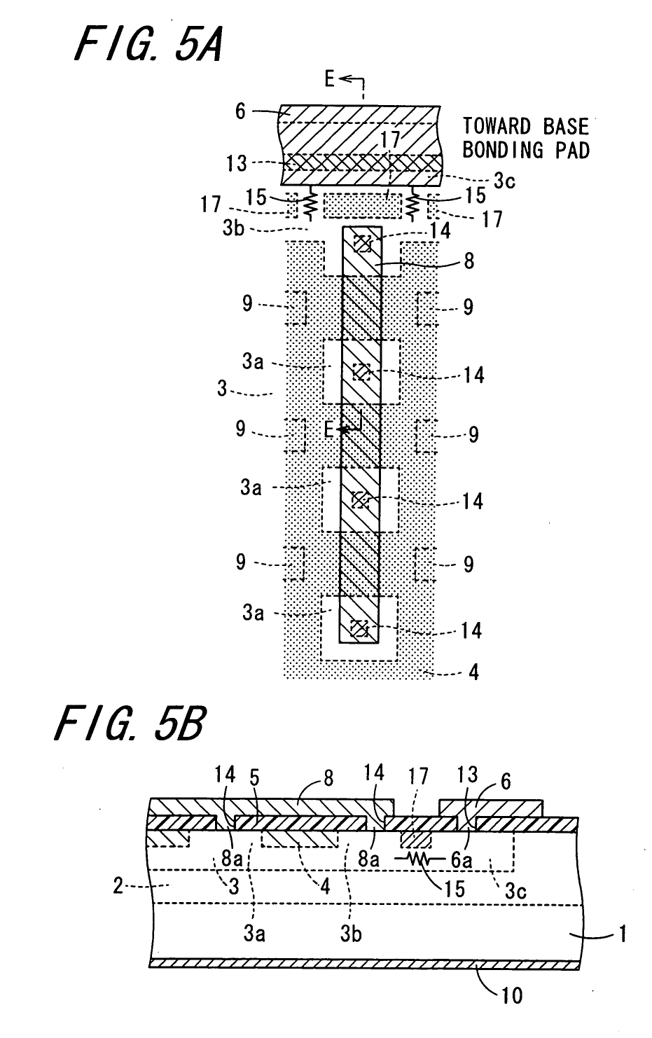

FIG. 5A is a plan view showing a relevant part of a mesh-emitter PNP transistor according to a fourth embodiment of the invention, and FIG. 5B is a sectional view taken on line E-E of FIG. 5A. In the mesh-emitter PNP transistor (referred to as a fourth transistor) according to the fourth embodiment, a plurality of island-shaped diffusion layers 17 of the same conductivity type as the P-type emitter layer, 4 is formed on the base layer 3d through which the first base wiring 6 and the second base wiring 8 are connected to each other. The base layer 3d through which the first base wiring 6 and the second base wiring 8 are connected to each other, functions as a ballast resistor 15. The fourth transistor has the same constitution regarding the other parts thereof as those of the first transistor.

According to the fourth transistor as described above, a plurality of the island-shaped diffusion layers 17 of the same conductivity type as the P-type emitter layer 4, is formed on the base layer 3d through which the first base wiring 6 and the second base wiring 8 are connected to each other, so that the ballast resistor 15 can be realized by these island-shaped diffusion layers 17. This makes it possible to achieve more reduction in cell size, compared to the conventional structure in which the emitter layer and the diffusion layer are applied in series with each other. The fourth transistor exerts more effects which are the same as those achieved by the first transistor.

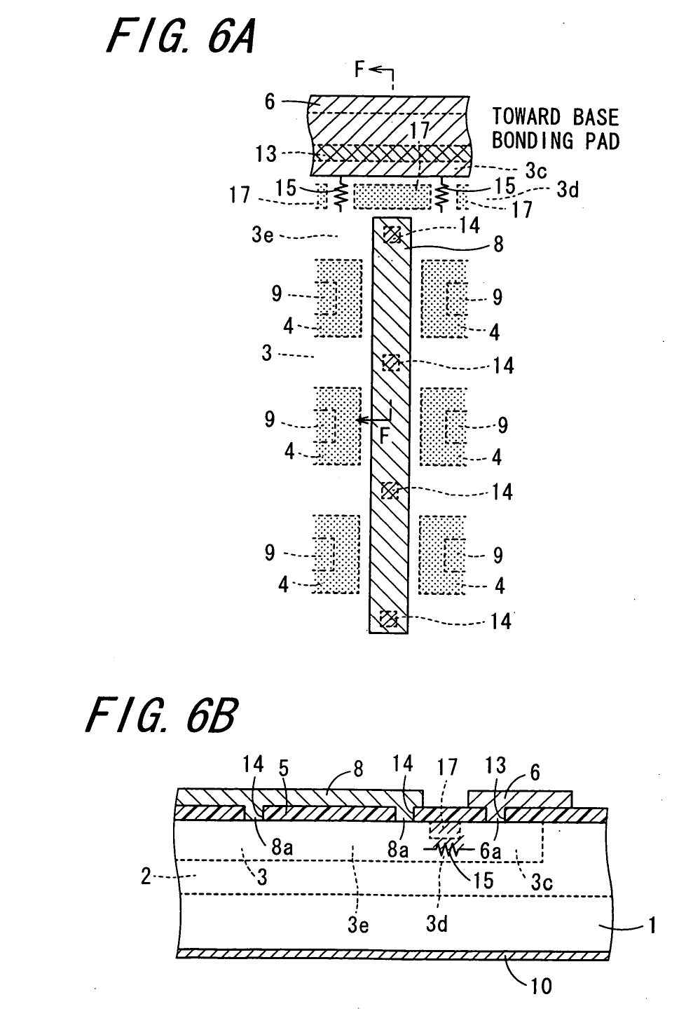

FIG. 6A is a plan view showing a relevant part of a multi-emitter PNP transistor according to a modified example of the fourth embodiment, and FIG. 6B is a sectional view taken on line F-F of FIG. 6A. In the multi-emitter PNP transistor according to the modified example, an island-shaped diffusion layer 17 of the same conductivity as the P-type emitter layer 4, is formed on the base layer 3d through which the first base wiring 6 and the second base wiring 8 are connected to each other. The base layer 3d through which the first base wiring 6 and the second base wiring 8 are connected to each other, functions as a ballast resistor 15. The multi-emitter PNP transistor according to the modified example has the same constitution regarding the other parts thereof as those of the second transistor.

According to the multi-emitter PNP transistor according to the modified example as described above, a plurality of the island-shaped diffusion layers 17 of the same conductivity type as the P-type emitter layer 4, is formed on the base layer 3d through which the first base wiring 6 and the second base wiring 8 are connected to each other, so that the ballast resistor 15 can be realized by these island-shaped diffusion layers 17. This makes it possible to achieve more reduction in cell size, compared to the conventional structure in which the emitter layer and the diffusion layer are applied in series with each other. The multi-emitter PNP transistor according to the modified example exerts more effects which are the same as those achieved by the second transistor.

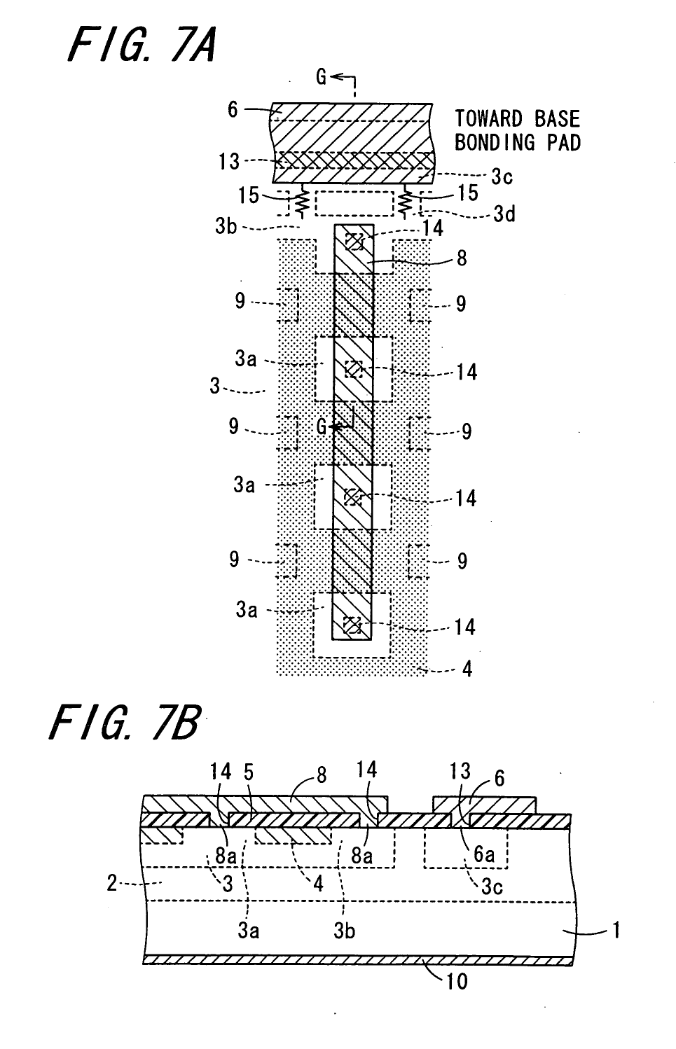

FIG. 7A is a plan view showing a relevant part of a mesh-emitter PNP transistor according to a fifth embodiment of the invention, and FIG. 7B is a sectional view taken on line G-G of FIG. 7A. In the mesh-emitter PNP transistor (referred to as a fifth transistor) according to the fifth embodiment, a base layer 3d is formed in a mesh shape through which base layer 3d the first base wiring 6 and the second base wiring 8 are connected to each other. The base layer 3d through which the first base wiring 6 and the second base wiring 8 are connected to each other, functions as a ballast resistor 15. The fifth transistor has the same constitution regarding the other parts thereof as those of the first transistor.

According to the fifth transistor as described above, the base layer 3d is formed in a mesh shape through which base layer 3d the first base wiring 6 and the second base wiring 8 are connected to each other. The base layer 3d formed in a mesh shape makes it possible to avoid electric field concentration with increase in cell size, and to enlarge its safe operating area. Furthermore, the saturation voltage across the collector and the emitter can be decreased so as to be lower than in the case of a conventional ballast resistor layout method.

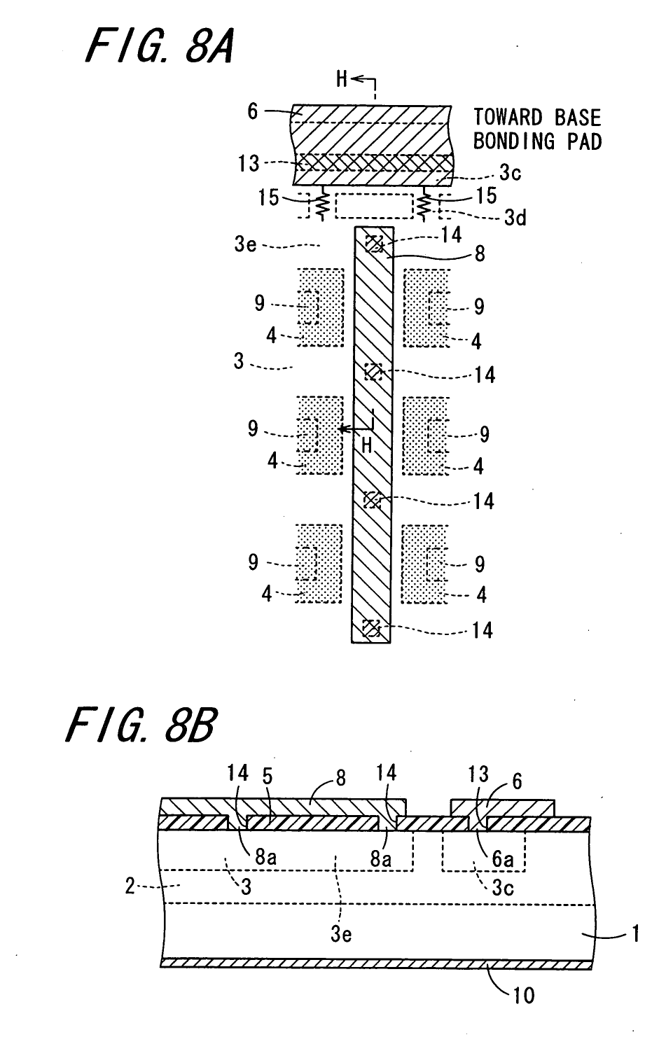

FIG. 8A is a plan view showing a relevant part of a multi-emitter PNP transistor according to a modified example of the fifth embodiment, and FIG. 8B is a sectional view taken on line H-H of FIG. 8A. In the multi-emitter PNP transistor according to the modified example, a base layer 3d is formed in a mesh shape through which base layer 3d the first base wiring 6 and the second base wiring 8 are connected to each other. The base layer 3d through which the first base wiring 6 and the second base wiring 8 are connected to each other, functions as a ballast resistor 15. The multi-emitter PNP transistor according to the modified example has the same constitution regarding the other parts thereof as those of the second transistor.

According to the multi-emitter PNP transistor according to the modified example as described above, the base layer 3d formed in a mesh shape makes it possible to avoid electric field concentration without increase in cell size, and to enlarge its safe operating area. Furthermore, the saturation voltage across the collector and the emitter can be decreased so as to be lower than in the case of a conventional ballast resistor layout method. The multi-emitter PNP transistor according to the modified example exerts more effects which are the same as those achieved by the second transistor.

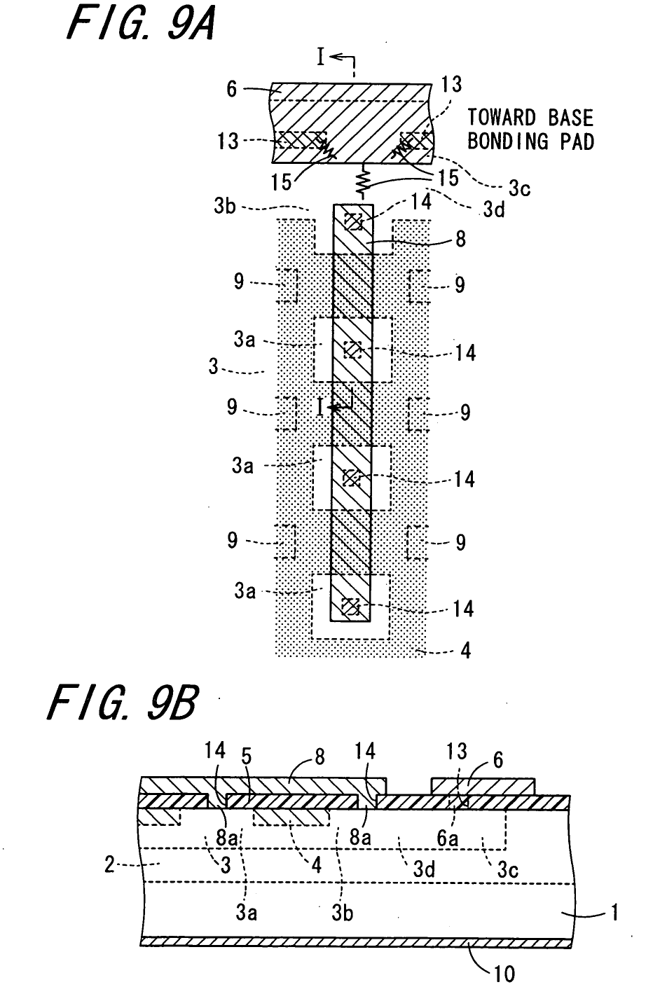

FIG. 9A is a plan view showing a relevant part of a mesh-emitter PNP transistor according to a sixth embodiment of the invention, and FIG. 9B shows a sectional view taken on line I-I of FIG. 9A. In the mesh-emitter PNP transistor (referred to as a sixth transistor) according to the sixth embodiment, a first base contact opening 13 is formed in a mesh shape which first base contact opening 13 is disposed for electrically connecting the base layer 3c and the first base wiring 6 to each other. The sixth transistor has the same constitution regarding the other parts thereof as those of the first transistor. In the embodiment, the first base contact opening 13 is formed in a mesh shape on the basis of the first transistor, but it is also possible to form the first base contact opening 13 into a mesh shape on the basis of either one of the third to fifth transistors.

According to the sixth transistor as described above, the base layer 3d through which the first base wiring 6 and the second base wiring 8 are connected to each other, functions as a ballast resistor 15 and in addition, the first base contact opening 13 is formed in a mesh shape, with the result that a current pathway of the first base contact opening 13 which pathway indicates a filling portion 6a of a conductive material which fills the first base contact opening 13, becomes narrower, thereby increasing a base-emitter resistance. Consequently, it is possible to enlarge a safe operating area.

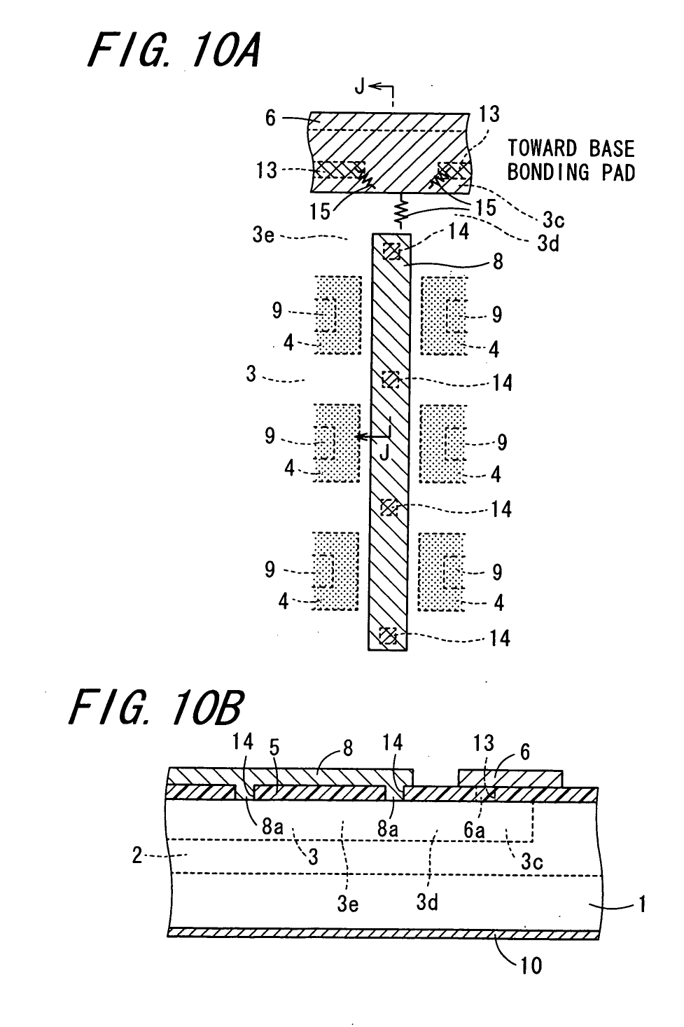

FIG. 10A is a plan view showing a relevant part of a multi-emitter PNP transistor according to a modified example of the sixth embodiment, and FIG. 10B is a sectional view taken on line J-J of FIG. 10A. In the multi-emitter PNP transistor according to the modified example, a first base contact opening 13 is formed in a mesh shape which first base contact opening 13 is disposed for electrically connecting the base layer 3c and the first base wiring 6 to each other. The multi-emitter PNP transistor according to the modified example has the same constitution regarding the other parts thereof as those of the second transistor. In the embodiment, the first base contact opening 13 is formed in a mesh shape on the basis of the second transistor, but it is also possible to form the first base contact opening 13 into a mesh shape on the basis of either one of the third to fifth transistors.

According to the multi-emitter PNP transistor according to the modified example as described above, the base layer 3d through which the first base wiring 6 and the second base wiring 8 are connected to each other, functions as a ballast resistor 15 and in addition, the first base contact opening 13 is formed in a mesh shape, with the result that a current pathway of the first base contact opening 13 which pathway indicates a filling portion 6a of a conductive material which fills the first base contact opening 13, becomes narrower, thereby increasing a base-emitter resistance. Consequently, it is possible to enlarge a safe operating area. The multi-emitter PNP transistor according to the modified example exerts more effects which are the same as those achieved by the second transistor.

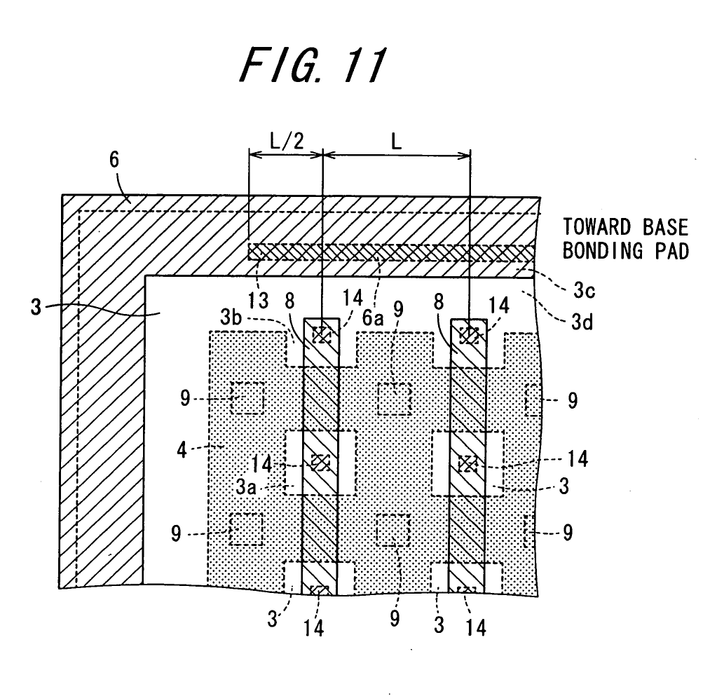

FIG. 11 is a plan view schematically showing a mesh-emitter PNP transistor according to a seventh embodiment of the invention. In the mesh-emitter PNP transistor (referred to as a seventh transistor) according to the seventh embodiment, an end portion of the filling portion 6a of the conductive material which fills the continuous first base contact opening 13, namely an end portion of the first base contact is formed so as to have a half length (L/2) of cell distance (L) in a direction parallel to an extending direction of the first base contact opening 13 between a second base contact openings 14. This end portion is defined as a portion of the filling portion 6a which portion extends outwardly from an intersection of an extended line of a second base wiring 8 at an outermost end with the filling portion 6a. In other words, the first base contact signified as the filling portion 6a can be regarded as an aggregation of a plurality of conducting strips which extend from the extended line of the second base wiring 8 as a center to two sides each by a half length (L/2) of the cell distance (L), that is, an aggregation of a plurality of conducting strips connected to each other, having the same length as the cell distance (L), with respect to one cell array composed of a plurality of cells connected to each other by the second base wiring 8. In other words, the first base contact thus configured can be regarded as a conductor composed of a plurality of the conducting strips having the length L which strips are connected to each other in the extending direction. The first base contact opening 13 is disposed so that an extending direction thereof is not parallel to an extending direction of the second base wiring 8. In other words, the first base contact opening 13 is disposed so that the extending direction thereof cuts across the second base wiring 8. The seventh transistor has the same constitution regarding the other parts thereof as those of the first transistor.

According to the seventh transistor as described above, an end portion of a conductive material which fills the first base contact opening 13 has a half length (L/2) of cell distance (L) in a direction parallel to an extending direction of the first base contact opening 13 between the second base contact openings 14, so that the conducting strip having the length L is allocated to each of the cell arrays. This makes it possible to equalize base currents flowing from the second base wirings 8. The first base contact opening 13 is disposed so that the extending direction thereof cuts across the second base wiring 8. Such constitution and disposition of the first base contact enable to equalize the base currents flowing from a plurality of the second base wirings 8.

The following transistor may be also formed as another embodiment of the invention. The first transistors are continuously disposed, but in a part thereof is formed a plurality of diffusion layers of the same conductivity type as the P-type emitter layer 4 as described in the third transistor. In this case, when lengths of a plurality of second base wirings disposed on a continuous first base wiring are different from each other, the second base wirings function as effective means for equalizing base currents. In all the embodiments, the PNP transistors are employed, but an NPN transistor can also be employed. Even the NPN transistor exerts the same effects as those in all the embodiments. It is also possible to embody the invention in embodiments to which various modifications are added within a scope of not departing from a purport of the invention.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A transistor structure having a base layer formed in a collector layer on a chip surface of a planar semiconductor, the transistor structure comprising:
an emitter layer formed in a base layer; and
an insulating layer formed on the base layer,
wherein a first base contact opening is formed in the insulating layer;
the first base contact opening is filled with a conductive material;
a first base wiring and a base electrode are formed on the insulating layer;
a second base contact opening is formed in the insulating layer on the base layer between the first base contact opening and the emitter layer which base layer is formed in the emitter layer or between the emitter layers;
the second base contact opening is filled with a conductive material;
a second base wiring is formed on the insulating layer; and
the first base wiring and the second base wiring are connected to each other by the base layer.

2. The transistor structure of claim 1, wherein a diffusion layer of the same conductivity type as the emitter layer is formed in the base layer through which the first base wiring and the second base wiring are connected to each other.

3. The transistor structure of claim 1, wherein a plurality of island-shaped diffusion layer of the same conductivity type as the emitter layer are formed in the base layer through which the first base wiring and the second base wiring are connected to each other.

4. The transistor structure of claim 1, wherein the base layer through which the first base wiring and the second base wiring are connected to each other, is formed into a mesh shape.

5. The transistor structure of claim 1, wherein the first base contact opening is formed in a mesh shape.

6. The transistor structure of claim 1, wherein an end portion of a filling portion of the conductive material portion which fills the continuous first base contact opening has a half length of cell distance in a direction parallel to an extending direction of the first base contact opening between the second base contact openings.

7. The transistor structure of claim 1, wherein the first base contact opening is disposed so that an extending direction thereof cuts across the second base wiring.

8. The transistor structure of claim 1, wherein the transistor is a mesh-emitter transistor of which emitter layer is formed in a mesh shape to be a mesh-emitter layer.

9. The transistor structure of claim 1, wherein the transistor is a multi-emitter transistor having an emitter layer composed of a plurality of island-shaped emitter layers.

10. An electronics device comprising the transistor structure of claim 1.
